(19) United States
(12) Patent Application Publication
(10) Pub. No.: US 2014/0090973 A1
(43) Pub. Date: Apr. 3, 2014

(54) DEVICE AND METHOD FOR ION BEAM SPUTTERING

(71) Applicants: Pascal Sortais, Meylan (FR); Thierry Lamy, Grenoble (FR)

(72) Inventors: Pascal Sortais, Meylan (FR); Thierry Lamy, Grenoble (FR)

(73) Assignee: CENTRE NATIONAL DE LA RECHERCHE SCIENTIFIQUE, Paris Cedex 16 (FR)

(21) Appl. No.: 13/984,234

(22) PCT Filed: Feb. 6, 2012
(86) PCT No.: PCT/FR12/50250

§ 371 Date: Dec. 16, 2013

(30) Foreign Application Priority Data
Feb. 8, 2011 (FR) 1150981

(51) Int. Cl. C23C 14/34

(52) U.S. Cl. CPC C23C 14/3442
USPC 204/192.11; 204/298.04

(57) ABSTRACT

The invention relates to a device for depositing a selected material on a substrate by means of ion beam sputtering, which include a plurality of targets of a selected material, each of which is bombarded by an ion beam, the lateral dimensions of each of the ion beams being less than one tenth of the lateral dimensions of the substrate.

### BACKGROUND

The present invention relates to a device and to methods of ion sputtering, that is, of deposition of particles on a substrate, said particles being generated by the bombarding by one or several ion beams of a target formed of one or several selected materials or of several targets of various selected materials.

### DISCUSSION OF THE RELATED ART

In an ion sputtering device, a beam of relatively heavy ions, for example, argon, is directed towards a target to cause the sputtering of particles of the material(s) forming this target. Part at least of these particles deposit on a substrate to form a thin layer of the material(s) thereon.

FIG. 1 very schematically illustrates the principle of an ion sputtering deposition. An ion source 1 emits an ion beam 3 towards a target 5 and the bombarded are of the target sputters particles of the target material, which are especially received on a substrate 7 onto which the considered material is desired to be deposited. This substrate is generally arranged in a plane parallel to the target plane and the point of impact of the ion beam on the target is located at the intersection of the target and of the normal running through the substrate center. The angle between this normal and an outer edge of the substrate is called θₘₐₓ.

FIG. 1 also shows in a dotted curve 9 the amount of particles emitted according to angle θ with respect to the normal to the target. It can be observed that this amount is maximum in the direction perpendicular to the target and decreases as angle θ increases. Generally, it is considered that the particle density is defined by a function of type (cosθ)ⁿ, with n generally ranging between 1 and 3. Thus, the sputtered material deposit on substrate 7 will be thicker at the substrate center than at its periphery.

To overcome this disadvantage and to obtain a deposit of substantially constant thickness on the substrate, various methods have been provided in prior art, among which the following can be mentioned.
Taking the substrate away from the target so that angle θₘₐₓ is small and comprised in the practically flat upper area of curve 9. This results in large installations, the distance between the target and the substrate for example being on the order of one meter. Large enclosures placed under vacuum thus have to be provided, which results in long pump-out times, and in the need to provide powerful pumping systems and to accurately estimate the mechanical resistance of the enclosure at the atmospheric pressure.
Enlargement of the target surface area, where the irradiated surface area of the target may substantially reach the substrate surface area. Such a solution also poses problems, especially to obtain a substantially homogeneous irradiation of the target, and results in high costs to obtain large targets made of ultra-pure materials.
Use of various electromagnetic deflectors to homogenize the ion beam distribution on the target and/or to homogenize the distribution of the particles of materials on the substrate. Such a solution is complex to implement and increases the cost of installations.
Use of mechanical systems for displacing the substrate according to a linear motion, or with planetary-type structures. Again, such a solution is complex to implement and increases the size and the cost of installations.
Use of several ion sources to bombard a target of large surface area. In practice, it is difficult to obtain a homogeneous irradiation of the target over a large surface area.

On the one hand, in most known installations, a same chamber is used for the ion source, and the target, and the substrate forming the vaporization area. Even if separate chambers are attempted to be used, these chambers communicate by a large opening capable of letting through an ion beam of large cross-section. This raises optimization issues.

An improved ion sputtering installation is thus needed.

### SUMMARY

An object of embodiments of the present invention is to provide an ion sputtering installation overcoming at least some of the disadvantages of prior art installations.

A more specific object of the present invention is to provide an ion sputtering installation enabling to obtain a deposit of regular thickness on a target and/or to obtain a deposit having it thickness varying according to the location on the target according to a predetermined rule.

Another object of the present invention is to provide such an installation where pressures practically independent in the ion source area and in the actual sputtering area can be obtained.

Thus, an embodiment of the present invention provides a device for depositing a selected material on a substrate by ion sputtering, comprising a plurality of targets of a selected material, each of which is bombarded by an ion beam, the lateral dimensions of each of the ion beams being smaller than one tenth of the lateral dimensions of the substrate.

According to an embodiment of the present invention, the device is adapted to the deposition of several selected materials and comprises several pluralities of targets, each plurality being associated with a material.

According to an embodiment of the present invention, the targets are symmetrically distributed around an axis of symmetry orthogonal to the substrate and inclined with respect to the normal thereto.

According to an embodiment of the present invention, the targets are arranged side by side in two lines on either side of said axis and form two surfaces of a prism.

According to an embodiment of the present invention, the targets are circularly distributed and form the surface of a cone.

According to an embodiment of the present invention, the device comprises a sputtering chamber and a chamber containing the ion beam sources, the chambers being separated by a wall provided with openings of small cross-section, corresponding to the cross-section of the ion beams, and pumping mean capable of maintaining distinct dynamic vacuums in the two chambers.

According to an embodiment of the present invention, the device comprises a system for rotating and/or shifting the assembly of targets.

According to an embodiment of the present invention, the device comprises a system for measuring the ion current of each beam placed under the assembly of targets and mobile therewith.

According to an embodiment of the present invention, the device further comprises a system performing at least one of the following functions: rotating-shifting, heating and/or plasma immersion, ion bombarding and/or cache, and substrate biasing.

An embodiment of the present invention provides a method for depositing one or several selected materials on a substrate by ion sputtering, comprising the steps of: arranging a plurality of targets of lateral dimensions smaller than one tenth of the lateral dimensions of the substrate around an axis orthogonal to the substrate; bombarding each of the targets with an ion beam; and selecting the distance between targets, the distance between targets and substrate, and the target orientation with respect to the substrate to obtain a selected deposition profile on the substrate.

### BRIEF DESCRIPTION OF THE DRAWINGS

The foregoing and other objects, features, and advantages will be discussed in detail in the following non-limiting description of specific embodiments in connection with the accompanying drawings, among which:

FIG. 1, previously described, is a simplified view illustrating an ion beam sputtering process;

FIG. 2 is a simplified view illustrating the operating principle of an ion sputtering device according to an embodiment of the invention;

FIGS. 3A to 3C are curves illustrating thickness variations of a deposited layer according to geometric parameters of an ion sputtering installation of the type in FIG. 2;

FIG. 4 is a perspective view illustrating an ion sputtering installation according to a first embodiment of the present invention; and

FIG. 5 is a perspective view illustrating an ion sputtering installation according to a second embodiment of the present invention.

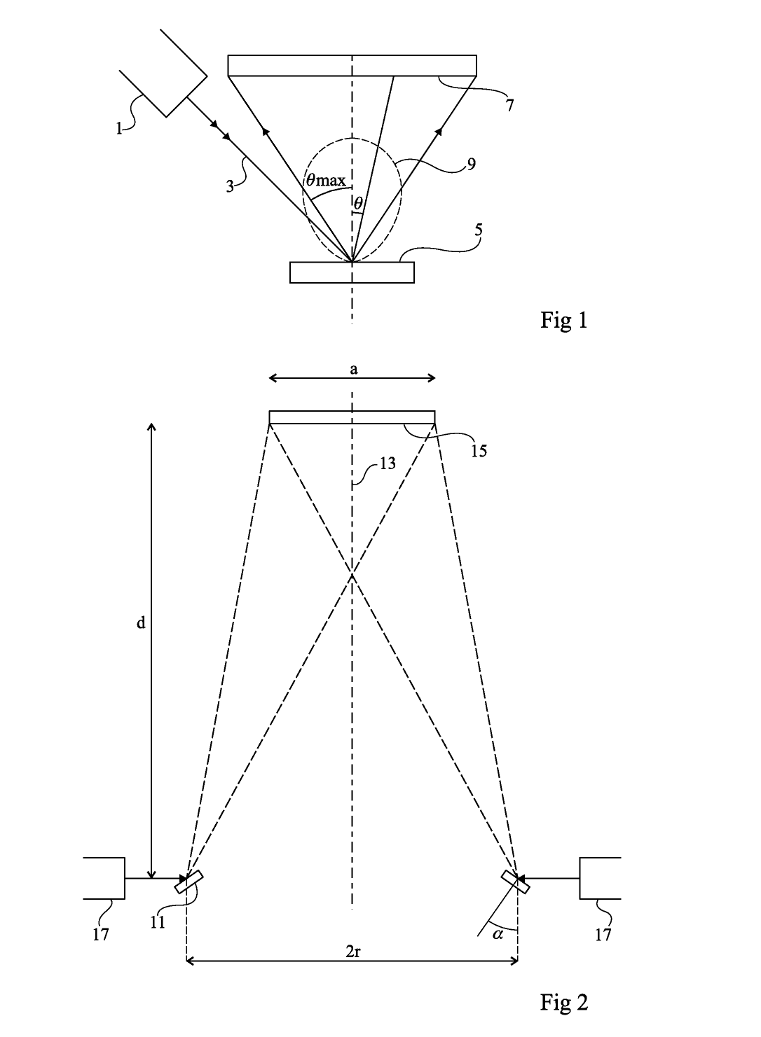

### DETAILED DESCRIPTION

FIG. 2 very schematically illustrates the operating principle of an ion sputtering device according to an embodiment of the present invention. In this device, several small targets 11 are provided around an axis 13 normal to a substrate 15 onto which a deposition is desired to be performed. Each of the targets is bombarded by an ion beam provided by sources 17.

The following references are used:

α, for the angle between the plane of a target and the direction of axis 13,

α, for the lateral dimension of the substrate (its diameter in the case of a circle or its side length in the case of a square),

2r, the distance between targets, and

d, the distance between the substrate and the projection on axis 13 of the center of targets 11.

It should then be noted that, according to the selection of parameters αa, d, and r, a selected deposition thickness profile can be obtained on the substrate.

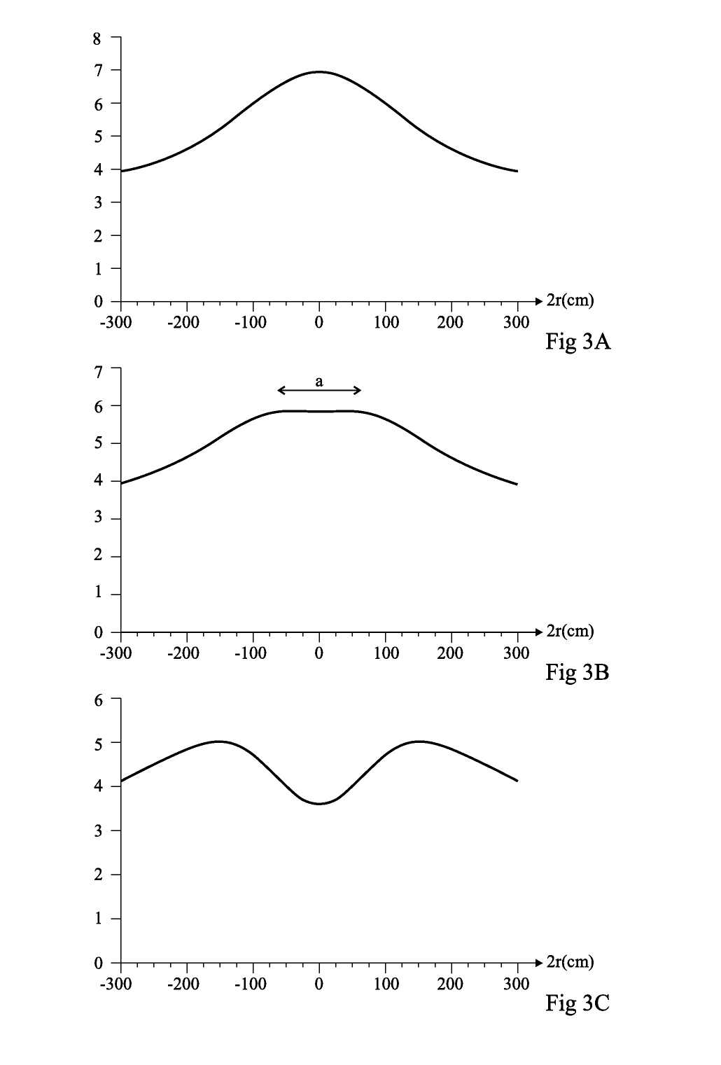

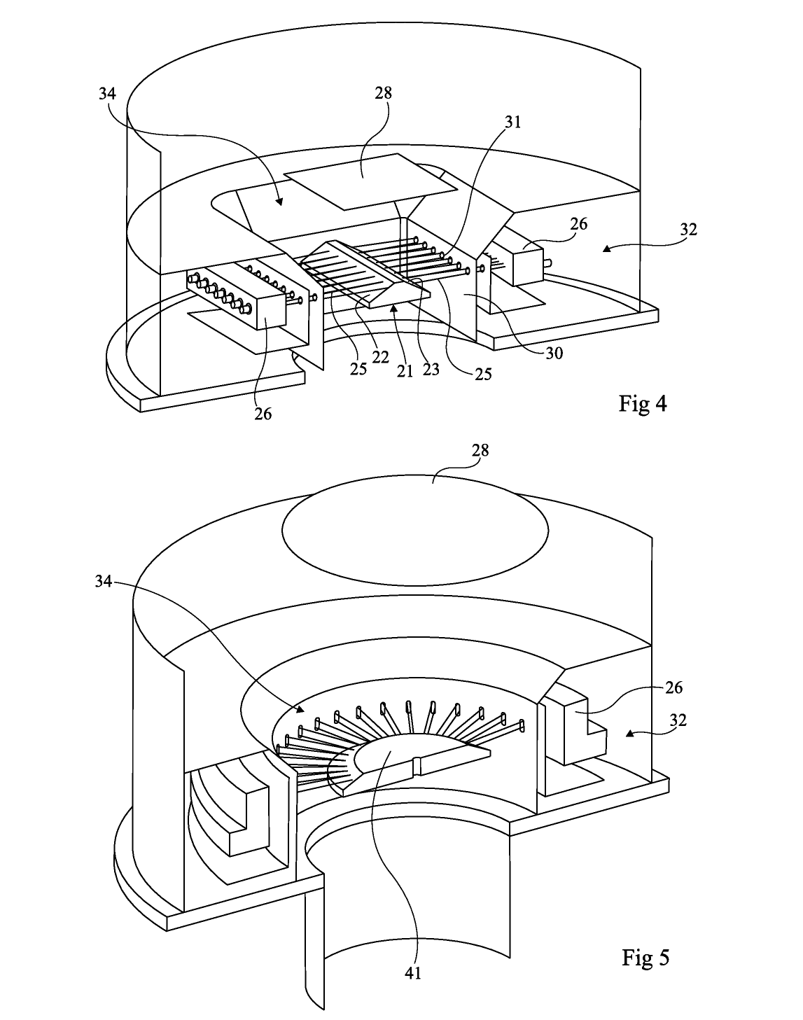

Three examples of thickness profile are given in FIGS. 3A, 3B, and 3C. In the three drawings, angle α is equal to 30° and distance d is equal to 15 cm. In the case of FIG. 3A, value r is equal to 2 cm. In the case of FIG. 3B, value r is equal to 4 cm and in the case of FIG. 3C, value r is equal to 8 cm. It can thus be observed that for a target-to-substrate distance of 15 cm only, as illustrated in FIG. 3B, a deposition homogeneity can be obtained (better than to within 5%) over a 15 cm distance. Specific profiles such as those illustrated in FIGS. 3A and 3C can also be obtained according to the values of distance r. The possibility of modifying angle a provides an additional adjustment parameter.

The examples of FIGS. 3A, 3B, and 3C applied to the simplified device of FIG. 2 are provided in the case of a purely one-dimensional analysis. If several sources are distributed at the periphery of axis 13 of FIG. 2, profiles such as that of FIG. 3B can be obtained over an entire plane.

Further, the example of FIG. 2 and of FIGS. 3A-3C has been given in the case where the ion beam almost forms a point on each target. In practice, the lateral dimensions of the cross-section of an ion beam on a target will not be those of a point but will be very small. These dimensions will be selected to be at least ten times smaller than those of the substrate, that is, the bombarded surface area of the target is more than one hundred times lower than the substrate surface area. Beam energies ranging between 10 and 20 kV will advantageously be chosen, and energies ranging between 0.1 and 10 kV may be used to finely adjust very small evaporation flows. The general flow at the substrate level corresponds to the sum of the components of each source.

As will be seen in the following embodiments, the targets, instead of being small distinct targets, may be small distinct portions of a same material surface.

FIG. 4 shows a first embodiment of an installation according to the present invention. In this example, the target has the shape of a prismatic element 21 having two opposite surfaces 22 and 23 receiving, on distinct areas, ion beams 25 originating from ion sources 26 arranged on either side of the prism. Each ion beam illuminates a small area of a surface of the prism. A substrate 28 is horizontally arranged above the prism. By properly selecting the distance (d) between the substrate and the prism, the apex angle (α) of the prism, and the distance (2r) between the points of impact on opposite surfaces of the prism, a substrate coating which may be homogeneous if conditions similar to those previously described in relation with FIG. 3B are selected is then obtained, while keeping, as previously indicated, a short distance between substrate 28 and the targets.

It should also be noted that in the example of installation shown in FIG. 4, the ion beams reach the prism by passing through openings 31 in a wall 30. Given the low cross-section of the ion beams, openings 31 may have small dimensions. Accordingly, all ion sources 26 may be placed in a peripheral chamber 32 distinct from a chamber 34 where the target prism and substrate 28 are placed. Chambers 32 and 34 only communicating through small openings 31, distinct dynamic vacuums can be created in chambers 32 and 34, which enables to independently optimize the operation of the ion sources and that of the sputtering area into which a reactant gas may be injected for the deposition of chemically-controlled layers.

FIG. 5, which will not be described in detail, shows an installation similar to that of FIG. 4 where, however, the targets areas, instead of corresponding to the two surfaces of a prism, correspond to the periphery of a cone 41. This provides a rotational structure which may be more advantageous in certain cases.

As multiple ion sources, ion sources of the type described in French patent application 08/57068 of Oct. 17, 2008 issued to the Centre National de la Recherche Scientifique, having as inventors P. Sortais and T. Lamy, may be used.

Different gases may be used for the ion beam, and while argon will currently be used, other gases generally provided in such ion sputtering systems may be used herein.

The target may be copper or any other simple or combined material. On the other hand, several different groups of targets may be used for different materials which are desired to be obtained in combination on the substrate. In this case, the invention advantageously enables to optimally adjust the ion beams on each of the targets of each of the groups of targets.

Various alterations, modifications, and improvements may be implemented. In particular:
the device may comprise a system for rotating and/or shifting the target assembly, to control the position and the shape of the target wearing area;
a system for measuring the ion current of each beam may be placed under the target assembly and be mobile therewith;
a system for rotating-shifting and/or heating and/or of plasma immersion and/or ion bombarding and/or cache and/or substrate biasing may be provided;
the device may comprise a system for modulating the intensity of the ion currents of the sources.

1. A device for depositing a selected material on a substrate by ion sputtering, comprising:
a plurality of targets of a selected material, each of which is bombarded by an ion beam, the lateral dimensions of each of the ion beams being smaller than one tenth of the lateral dimensions of the substrate;
a sputtering chamber containing the targets and the substrate, and a chamber containing the ion beam sources, the chambers being separated by a wall provided with openings having a cross-section corresponding to the cross-section of the ion beams; and
a pump configured to maintain distinct dynamic vacuums in the two chambers.

2. The device of claim 1, capable wherein the device is configured to deposit several selected materials, comprising several pluralities of targets, each plurality being associated with a material.

3. The device of claim 1, wherein the targets are symmetrically distributed around an axis of symmetry orthogonal to the substrate and inclined with respect to the normal thereto.

4. The device of claim 3, wherein the targets are arranged side by side in two lines on either side of said axis and form two surfaces of a prism.

5. The device of claim 3, wherein the targets are circularly distributed and form the surface of a cone.

6. The device of claim 1, comprising a system for rotating and/or shifting the assembly of targets.

7. The device of claim 1, comprising a system for measuring the ion current of each beam placed under the target assembly and mobile therewith.

8. The device of claim 1, further comprising a system performing at least one of the following functions: rotating-shifting, heating and/or plasma immersion, ion bombarding and/or cache, and substrate biasing.

9. A method for depositing one or several selected materials on a substrate by ion sputtering, comprising the steps of:
bombarding each of a plurality of targets of the one or several selected materials with an ion beam; and
selecting the distance (2r) between targets, the distance (a) between targets and substrate, and the target orientation (α) with respect to the substrate to obtain a selected deposition profile on the substrate.

10. The method of claim 9, further comprising symmetrically distributing the targets around an axis of symmetry orthogonal to the substrate and inclined with respect to the normal thereto.

11. The method of claim 10, further comprising arranging the targets side by side in two lines on either side of the axis to form two surfaces of a prism.
